(19) United States
(12) Patent Application Publication
(10) Pub. No.: US 2026/0252254 A1
(43) Pub. Date: Aug. 27, 2026

(54) ELECTRONIC DEVICE AND METHOD

(71) Applicant: STMicroelectronics International N.V., Geneva (CH)

(72) Inventors: Raphael Clauss, St Egreve (FR); Chrislain Dallery, Le Grand Lemps (FR); Jerome Lacan, Trets (FR)

(21) Appl. No.: 19/468,632

(22) Filed: Feb. 3, 2026

(30) Foreign Application Priority Data
Feb. 5, 2025 (FR) 2501172

(51) Int. Cl. G06F 3/06

(52) U.S. Cl. CPC G06F 3/065; G06F 3/0611; G06F 3/0688

(57) ABSTRACT

The present description concerns an electronic device, and associated method, including a first non-volatile phase-change memory having a first and a second write modes, each write mode having a different maximum number of write cycles, and at least one finite state machine configured to copy data from the first memory written with the first write mode, and to rewrite the data with the second write mode.

### CROSS-REFERENCE TO RELATED APPLICATIONS

This application claims the priority benefit of French patent application number FR2501172, filed on Feb. 5, 2025, entitled “Dispositif électronique”, which is hereby incorporated herein by reference to the maximum extent allowable by law.

### TECHNICAL FIELD

The present disclosure generally concerns electronic devices and their operating methods.

### BACKGROUND

Non-volatile phase-change memories (PCMs), such as those incorporated in microcontrollers, are potentially sensitive to high temperatures such as those used during soldering steps. This may generate the alteration of data written into these memories prior to the soldering step.

### SUMMARY

There exists a need to obtain an electronic device enabling to address cases where it is soldered before or after the writing of data into the memory, while keeping a satisfactory maximum number of write cycles.

An embodiment overcomes all or part of the disadvantages of known devices.

An embodiment provides an electronic device provided with a first non-volatile phase-change memory having a first and a second write modes, each write mode having a different maximum number of write cycles; the device comprising at least one finite state machine configured to copy data from the first memory written with the first write mode, and to rewrite them with the second write mode.

An embodiment provides a method of operation of an electronic device provided with a non-volatile phase-change memory having a first and a second write modes, each write mode having a different maximum number of write cycles; the method comprising the implementation, with a finite state machine, of a copying, and of a rewriting with the second write mode, of data from the first memory written with the first write mode.

According to an embodiment, the rewriting with the second write mode is performed in place of the corresponding data written with the first write mode.

According to an embodiment, the data copied before rewriting are stored in a second memory, which is volatile.

According to an embodiment, the data are in the form of a word and of a header containing information indicating the write mode used to write the corresponding word.

According to an embodiment, the finite state machine is configured to sequentially read the headers of words of the first memory and, each time the read header comprises the information according to which the corresponding word has been written with the first write mode, then this word is copied and rewritten with the second write mode into the same memory location.

According to an embodiment, the finite state machine is configured so that when the read header comprises the information according to which the corresponding word has been written with the first write mode, then prior to rewriting with the second write mode, this word is also stored and written into a first region of the first memory with the second write mode; and a memory location indicator is updated to correspond to the memory location of the word written with the first write mode, so that the rewriting is performed at the memory location given by the indicator.

According to an embodiment, the finite state machine is configured to sequentially read groups of words stored in the first memory and, when the header of at least one of the words of one of the groups comprises the information according to which the corresponding word has been written with the first write mode, then all the words of this group are copied with their respective header, and then rewritten with the second write mode into the same memory location.

According to an embodiment, each time the header of at least one of the words of one of the groups comprises the information according to which the corresponding word has been written with the first write mode, then, before rewriting with the second write mode, all the words in the group are also written into a first region of the first memory with the second write mode, and a memory location indicator is updated to correspond to the memory location of the group comprising the word(s) written with the first write mode, so that the rewriting is performed at the memory location given by the indicator.

According to an embodiment, the rewriting is carried out from the first region if the indicator is valid, or from the second memory if the indicator is not valid.

According to an embodiment, a data item written with the first write mode prior to a step of soldering of the device, has a stable value during the soldering step; or a data item written with the second write mode prior to a step of soldering of the device, has a value which is not stable during the soldering step.

According to an embodiment, the first and the second write modes comprise the application of a current pulse of different shape.

According to an embodiment, the maximum number of write cycles of the second write mode is at least twice, for example at least five times, preferably at least ten times, greater than the maximum number of write cycles of the first write mode.

According to an embodiment, the crystallinity of memory sectors of the first memory after writing is different for the two write modes.

According to an embodiment, the at least one state machine is arranged in a memory interface of the first memory.

According to an embodiment, the first memory comprises a plurality of memory banks, the device comprising one state machine per memory bank.

According to an embodiment, the device is a microcontroller.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, very schematically and in the form of blocks, an example of an electronic device of the type to which the described embodiments apply;

FIG. 2 shows, very schematically, blocks of FIG. 1 according to an embodiment;

FIG. 3 shows an operating method of the example of FIG. 2 according to an embodiment; and

FIG. 4 shows an operating method of the example of FIG. 2 according to an embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

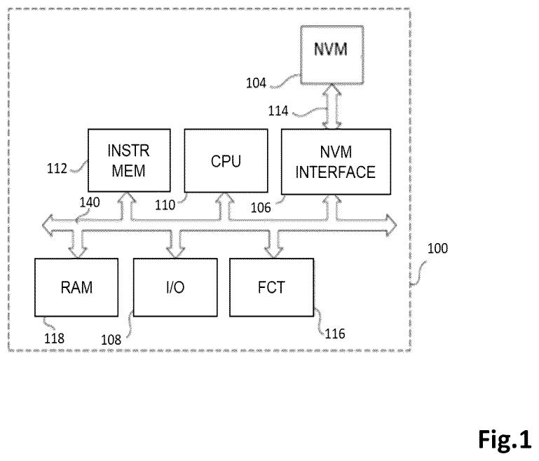

FIG. 1 shows, very schematically and in the form of blocks, an example of an electronic device 100 of the type to which the described embodiments apply. Device 100 is, for example, a microcontroller or a system on chip (SOC).

Electronic device 100 comprises a non-volatile memory 104 (NVM), of phase-change memory (PCM) type, capable of communicating, via a communication bus 114, with a non-volatile memory interface 106 (NVM INTERFACE), otherwise known as a memory controller, configured among others to write or read data into and from non-volatile memory 104.

Electronic device 100 further comprises, for example, a processing unit 110 (CPU) comprising one or more processors under control of instructions stored in an instruction memory 112 (INSTR MEM). Instruction memory 112 is, for example, a volatile random access memory (RAM). Processing unit 110 and memory 112 communicate, for example, via a system (data, address, and control) bus 140. Memory 104 is coupled to system bus 140 via non-volatile memory interface 106 and via bus 114. Device 100 further comprises an input/output interface 108 (I/O interface) coupled to system bus 140 to communicate with the outside.

Electronic device 100 for example comprises a volatile memory 118 (RAM), for example of RAM or MRAM type, coupled for example to system bus 140, for example via a memory interface.

Electronic device 100 may integrate other circuits implementing other functions (for example, one or more volatile and/or non-volatile memories, or other processing units), symbolized by a block 116 (FCT) in FIG. 1. Among these other circuits, device 100 comprises, for example, a read-only or static memory.

Memory 104 is for example partitioned into different banks or regions comprising one or more memory sectors. In a phase-change memory 104, these sectors may be rewritten directly without requiring a prior erase operation. The writing into these sectors is achieved by changing their crystalline or amorphous phase, which are associated with different resistances, for example by the application of a voltage or current pulse at the time of writing. The shape of the voltage or current pulse determines the crystalline phase of the memory sector written into.

A plurality of write modes have recently been developed to write data into phase-change memories. A first write mode (called power_mode) allows a maximum number of write cycles which is low, for example lower than ten cycles, preferably lower than or equal to a thousand cycles, but with a high resistance to temperature of the written information, for example higher than the standard soldering temperature of electronic components. A second write mode (called user_mode), allows a higher maximum number of write cycles, for example in the order of 10,000 cycles, but with a temperature resistance of the written data that may be affected by the standard soldering temperature of electronic components. In an example, the maximum number of write cycles of the second write mode user_mode is at least twice, for example at least five times, preferably at least ten times, greater than the maximum number of write cycles of the first write mode (power_mode). The performance in terms of cycling of the different write modes is linked, for example, to a change in crystallinity of the memory sectors depending on the selected write mode. Data written in the write mode allowing a high cycling may thus happen to be corrupted or erased, in other words are not robust, when the electronic device is soldered.

Certain applications using memory 104 may be implemented in factory by the device manufacturer, and others may be loaded by external providers who will solder the microcontroller in a product before or after writing of the data. It is thus difficult to predict at what time the device will be soldered.

On the other hand, conventional non-volatile memories, that is, those which are not phase-change memories, allow a high write cycling without however being overly sensitive to temperature. Customers or service providers should thus be allowed to use phase-change memories in a way close to the use of conventional non-volatile memories.

It may be envisaged to write into the memory before soldering with the first mode and then to write, after soldering, with the second mode, however certain applications may be impacted if different types of write mode are mixed within memory 104.

Software solutions can be envisaged, but in certain security-related cases, certain data are not accessible by processing unit 110, which implies the impossibility to modify by software means the write mode on these data.

On the other hand, the writing time associated with the first write mode may be too long for some applications.

To overcome these problems, the embodiments provide an electronic device provided with a first non-volatile phase-change memory having a first and a second write modes, each write mode having a different maximum number of write cycles; the device comprising at least one finite state machine configured to copy data from the first memory written with the first write mode, and to rewrite them with the second write mode.

This enables to be faster than a software solution, for example, since a plurality of banks of the memory can be processed at the same time. Further, only all or part of the memory words written with the first mode are rewritten with the second mode.

This further enables to avoid too long a programming time during the product lifetime, for example with an implementation during a production phase or during a first use.

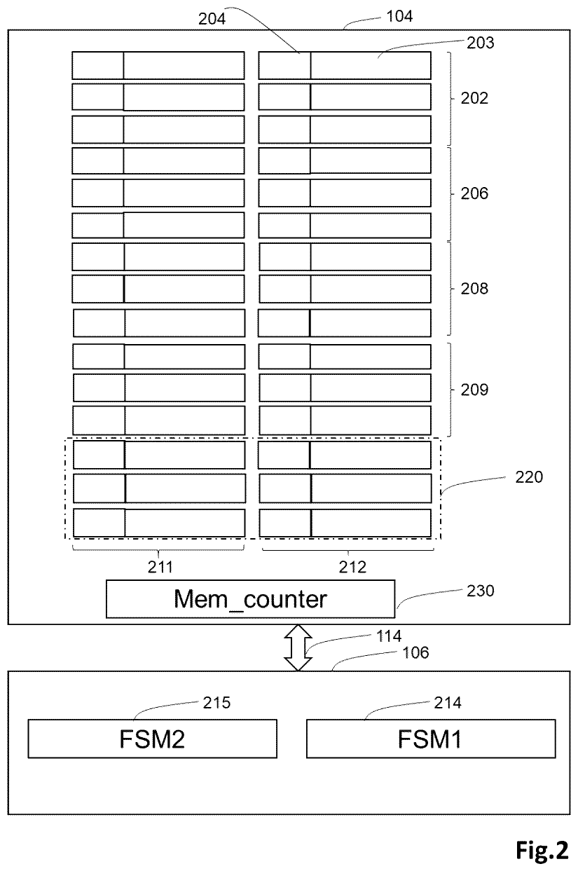

FIG. 2 shows, very schematically, blocks of FIG. 1 according to an embodiment.

More particularly, the example of FIG. 2 shows memory 104 and optionally memory interface 106 if it is present.

In the shown example, the memory comprises a plurality of data banks 211, 212. Each bank contains data in the form of words 203, for example 128 bits long. Each word comes along with a header or private 204, for example a private or secure header. The header comprises, for example in the form of a bit, the write mode used to write the corresponding word.

Data words 203 may be gathered into pages 202, 206, 208, 209, which for example gather three words as illustrated, or, as not illustrated, eight or sixteen words or any other number of words. This allows a processing faster than word by word.

The header for example further comprises an error-correcting code (ECC) linked to the corresponding word, or other information linked to the corresponding word.

In the shown example, memory 104 comprises, for example, a memory region 220 in which is stored one or more words or a page, in case, for example, of a power outage during a copying or a rewriting of words or pages.

In the shown example, memory 104 comprises, for example, a memory space for storing the value 230 (Mem_counter) of a counter. In an example, the counter is implemented in memory interface 106.

In the example of FIG. 2, two finite state machines 214 (FSM1) and 215 (FSM2) are implemented within memory interface 106. In the shown example, finite state machine 214 is dedicated to data bank 212, and finite state machine 215 is dedicated to data bank 211. The state machines may be active at the same time or in a staggered way.

In a non-illustrated example, the number of these finite state machines is different from two, for example equal to one, or equal to the number of data banks 211, 212.

In an example, the finite state machine(s) are implemented within memory 104 or within another element of device 100.

The finite state machines are configured to copy all or part of the data of memory 104 which have been previously written with the first write mode power_mode, and to rewrite them with the second write mode user_mode. The rewriting with the second write mode is performed, for example, in place of the data previously written with the first write mode. In other words, if data are written with the first write mode, then the dedicated state machine will copy these data to then rewrite them, that is, replace them, while keeping the same values, but this time with the second write mode.

Prior to the rewriting with the second write mode user_mode, the data written with the first write mode are copied, that is, temporarily stored, for example in a volatile memory such as memory 118.

In an example, finite state machine(s) 214, 215 are configured to sequentially read the headers 204 of words 204 from memory 104. Each time they read a header 204 comprising the information according to which the corresponding word 203 has been written with the first write mode, then this word, as well as the corresponding header, are copied, for example into memory 118, and then rewritten with the second write mode, for example at the same memory location as the initial data. In an example, all the headers of a data bank are read, and the words having data written with the first write mode are then copied as well as their respective header, and then rewritten with the second write mode.

In an example, finite state machine(s) 214, 215 are configured to sequentially read the headers of words from memory 104. Each time they read a header 204 comprising the information according to which the corresponding word has been written with the first write mode power_mode, then this word, and the respective header, are optionally copied, for example into memory 118, and then rewritten with the second write mode, for example at the same memory location as the initial data. In an example, all the headers of a data bank are read, and the words written with the first write mode are then copied into a temporary memory and then rewritten with the second write mode.

In another example, finite state machine(s) 214, 215 are configured to read the groups of words 202, 206, 208, 209, sequentially, that is, one after the other. When the header of at least one of the words of one of these groups comprises the information according to which the corresponding word has been written with the first write mode, then all the words in this group, whether they are written with the first or the second write mode, are optionally copied, for example into memory 118, and then the entire group is rewritten with the second write mode, for example at the same memory location as the initial group.

A power loss may however happen to occur during the recopying or rewriting of data. This might result in a loss of information and damage device 100.

To overcome this, in an optional example related to the case where the headers are read one by one, finite state machine(s) 214, 215 are configured so that when the read header includes the information according to which the corresponding word has been written with the first write mode, then before rewriting with the second write mode, this word is stored, in other words, copied, and written into the buffer memory region 220 of memory 104. In an example, this copying is performed with the second write mode. The value of counter 230 is then updated. The value of counter 230 then corresponds, for example, to the memory location of the word and of its header which have been copied. Thus, the value of counter 230 may be used as an indicator of the memory location for rewriting, with the second write mode, after the power has been restored. The rewriting is thus resumed at the memory location corresponding to the indicator.

A similar optional example may be implemented by copying, this time sequentially, into memory region 220, the group(s) 202, 206, 208, 209 identified as comprising at least one word having been written with the first write mode.

In an example, at the starting of the state machine(s), if the counter is valid, the header saved in memory region 220 is rewritten at the position given by the counter.

In an example, the counter value further comprises its complement. For example, value 0xAA00 of the counter is associated with value 0x55FF. This enables to identify errors by redundancy.

When the copying with the second write mode is carried out, the counter value is made non-valid, for example by making the value and its complement equal. For example, if the counter value is 0xFFFF and its associated complement is 0xFFFF, then the counter is invalid.

In an example, all the words written with the first write mode are not necessarily rewritten with the second write mode, even if their header has been read and they have been identified as written with the first write mode.

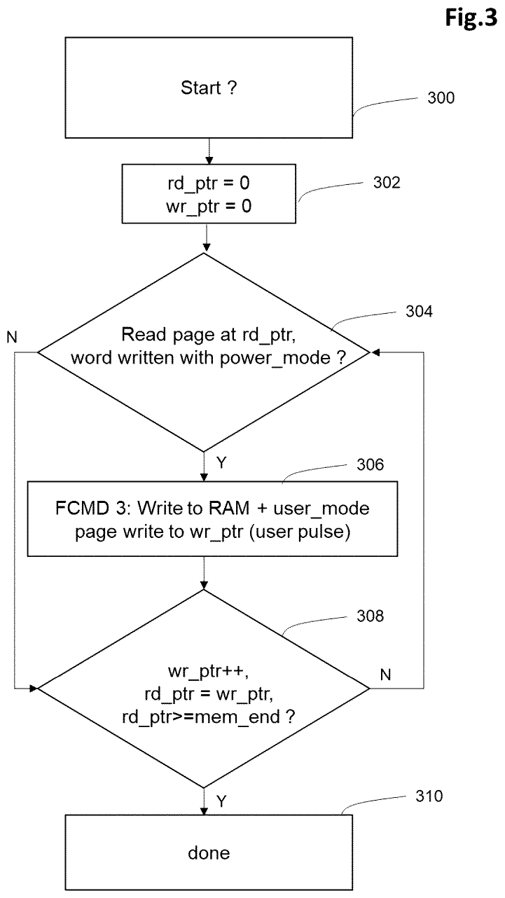

FIG. 3 shows an operating method of the example of FIG. 2 according to an embodiment. More particularly, the example of FIG. 3 illustrates an operating method in the case where memory region 220 and counter 230 are not implemented or not present.

In a first step 300 (Start?), the method begins.

At a step 302 (rd_ptr=0 wr_ptr=0), subsequent to step 300, a read pointer rd_ptr, for example a volatile register, is set to zero. Read pointer rd_ptr indicates, in memory 104, at which memory address the reading of a page or of word takes place. In this step, a write pointer wr_ptr, which may be a volatile register, is also set to zero. Write pointer wr_ptr indicates, in memory 104, at which address to write the copied word(s) and their associated header.

In an optional step 304 (Read page at rd_ptr, word written with power_mode?), the page, or the word and/or the header associated with this word, are read from the location of pointer rd_ptr. If at least one header read from the page, or from the word, indicates that at least one word has been written with the first write mode, then (Y branch) a step 306 (FCMD 3: Write to RAM+User_mode page write to wr_ptr (user pulse)) is implemented. If no header read from the page, or from the word, indicates that a word has been written with the first write mode, then (N branch) a step 308 (wr_ptr++, rd_ptr=wr_ptr, rd_ptr>=mem_end?) is implemented.

At step 306, the page, or the word and its header are written into a temporary buffer memory, such as memory 118, for example. Then, they are written, at the location of pointer wr_ptr, and with the second write mode. In other words, the data are rewritten with the second write mode at the original location of the page, or of the word and of the associated header, written with the first write mode. After step 306, step 308 is implemented.

At step 308, pointer wr_ptr is incremented, in the case of the reading by page, by a value corresponding to the next page (for example 16 words ahead depending on the selected granularity), or in the case of a reading by individual words, by a value corresponding to the address of the next word. In other words, at step 308, pointer wr_ptr is incremented according to the selected granularity (page, word or set of words).

Pointer rd_ptr is also incremented to be equal to wr_ptr. If the value of pointer rd_ptr is greater than or equal to a value mem_end which corresponds to the end of the memory space in memory 104 dedicated to the data to be rewritten, then (branch Y) a step 310 (done) is implemented and the method has ended. Otherwise (N branch), the method continues by carrying out step 304 again, and so on.

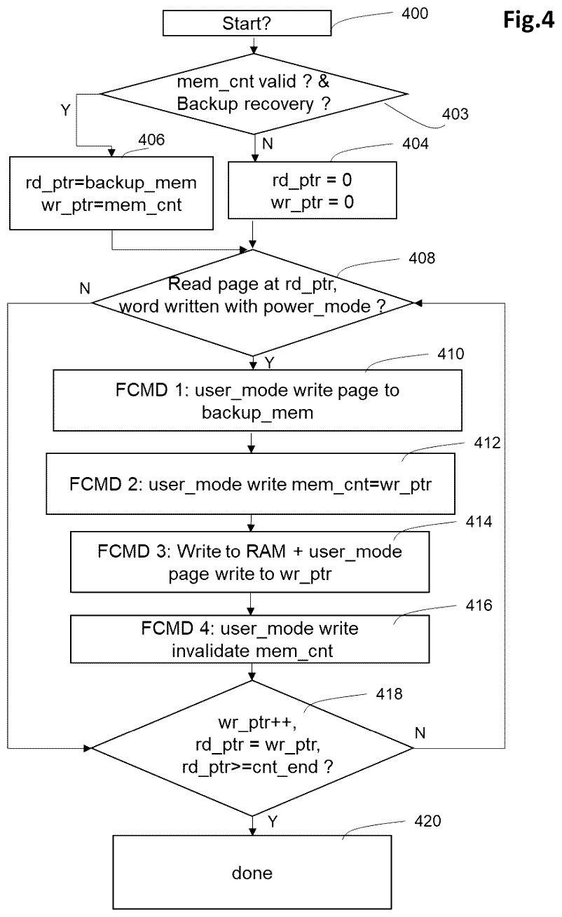

FIG. 4 shows an operating method of the example of FIG. 2, according to an embodiment. In particular, the example of FIG. 4 illustrates an operating method where memory region 220 and counter 230 are implemented.

At a step 400 (Start?), the method begins.

At a step 403 (mem_cnt valid? & Backup recovery?), which follows, for example, step 400, counter 230 is read and it is checked whether it is necessary to call up a data recovery from memory region 220, for example because the previous method was stopped during execution by a power outage.

After the reading of counter 230, if counter 230 is valid, for example when the counter value is equal to its complement, then a recovery step 406 (rd_ptr=backup_mem wr_ptr=mem_cnt) is implemented. If counter 230 is not valid (branch N), then a step 404 (rd_ptr=0 wr_ptr=0) is implemented.

Step 404 is similar to the step 304 of FIG. 3.

At step 406, pointer rd_ptr is set to the stored value backup_mem of counter 230, which corresponds to region 220. The reading is thus started, at the position given by the counter, that is, in region 220. The value of pointer wr_ptr is mem_cnt, which corresponds to the value of counter 230. The data present in memory region 220 are thus restored, that is, written with the second write mode, at the position given by the counter.

Steps 404 and 406 are followed by a step 408 (Read page at rd_ptr, word written with power_mode?) in which the data (page or word with header) present at the level of pointer rd_ptr are read and if at least one word has been written with the first write mode, then branch Y is taken and a step 410 (FCMD 1: user_mode write page to backup_mem) is implemented. If no word has been detected as having been written with the first write mode, then branch N is taken and a step 418 (wr_ptr++, rd_ptr=wr_ptr, rd_ptr>=cnt_end?) is implemented.

At step 410, the data (page or word with header, for example, depending on the selected granularity) present at pointer rd_ptr are written with the second write mode into region 220.

Step 410 is followed by a step 412 (FCMD 2: user_mode write mem_cnt=wr_ptr) where the value mem_cnt of counter 230 is equal to value wr_ptr, optionally with the corresponding error correction code.

Step 412 is followed by a step 414 (FCMD 3: Write to RAM+user_mode page write to wr_ptr), which is similar to step 306. At step 414, the data stored at the level of pointer rd_ptr, that is, in region 220, are optionally written into the temporary memory, for example memory 118, and then written, with the second write mode, at the location described by the counter value mem_cnt.

Step 414 is followed by a step 416 (FCMD 4: user_mode write invalidate mem_cnt), in which counter 230 is invalidated by writing into it an invalid value with the second write mode. An invalid value is, for example, a value copied twice identically, such as for example 0xFFFF/0xFFFF.

Step 416 is followed by step 418, in which pointer wr_ptr is incremented according to the selected granularity (page or word). In this step, pointer rd_ptr is also at a value equal to pointer wr_ptr. Further, if pointer rd_ptr has a value greater than or equal to an end value cnt_end of counter 230, then (Y branch) a method end step 420 (done) is implemented. If pointer rd_ptr has a value smaller than value cnt_end, then step 408 is implemented.

The embodiment of FIG. 4 allows a rewriting process which is robust to a power outage, for example.

Various embodiments and variants have been described. Those skilled in the art will understand that certain features of these various embodiments and variants may be combined, and other variants will occur to those skilled in the art. In particular, finite state machines 214, 215 may be arranged elsewhere than in memory interface 106, such as for example in memory 104 or in one of blocks 110 or 116.

Finally, the practical implementation of the described embodiments and variants is within the abilities of those skilled in the art based on the functional indications given hereabove. In particular, even if the described embodiments provide a rewriting of a word or of a page previously written with the first write mode, with the second write mode, it is possible to envisage this rewriting without for the headers to first be examined. Thus, it is possible, in the example of FIG. 3, to directly proceed from step 302 to step 306. In this case, the N branch of step 308 will directly be directed to step 306. Similarly, it is possible, in the example of FIG. 4, to directly proceed from steps 404 or 406 to step 410. In this case, the N branch of step 418 will directly be directed to step 410.

What is claimed is:

1. An electronic device comprising:
a first non-volatile phase-change memory having a first write mode and a second write mode, the first write mode having a different maximum number of write cycles than the second write mode; and
at least one finite state machine configured to:
copy data from the first memory written with the first write mode; and
rewrite the copied data with the second write mode.

2. The device according to claim 1, wherein the at least one finite state machine is configured to rewrite the copied data with the second write mode in place of the data written with the first write mode.

3. The device according to claim 1, wherein the at least one finite state machine is configured to store the copied data in a volatile memory.

4. The device according to claim 1, wherein the data are in a form of a word and a header containing information indicating the first or second write mode used to write the word.

5. The device according to claim 4, wherein the finite state machine is configured to:
sequentially read headers of words of the first memory; and
each time a read header comprises the information according to which a corresponding word has been written with the first write mode, copy and rewrite the corresponding word with the second write mode into a same memory location.

6. The device according to claim 5, wherein the finite state machine is configured to, in response to the read header comprising the information according to which the corresponding word has been written with the first write mode, then, prior to rewriting with the second write mode, also store and write the corresponding word in a first region of the first memory with the second write mode; and
update a memory location indicator to correspond to a memory location of the word written with the first write mode, so that the rewriting is performed at the memory location given by the indicator.

7. The device according to claim 4, wherein the finite state machine is configured to:
sequentially read groups of words stored in the first memory; and
in response to the header of at least one of the words of one of the groups comprising the information according to which a corresponding word has been written with the first write mode, then copy all words of the one of the groups are copied with their respective header, and then rewrite with the second write mode into a same memory location.

8. The device according to claim 7, wherein the finite state machine is configured to:
each time the header of at least one of the words of one of the groups comprises the information according to which the corresponding word has been written with the first write mode, then, before rewriting with the second write mode, also write all words in the one of the groups into a first region of the first memory with the second write mode; and
update a memory location indicator to correspond to the memory location of the one of the groups comprising the words written with the first write mode, so that the rewriting is performed at the memory location given by the indicator.

9. The device according to claim 6, wherein the at least one finite state machine is configured to:
store the copied data in a volatile memory; and
perform the rewriting from:
the first region in response to the indicator being valid; or
from the volatile memory in response to the indicator not being valid.

10. The device according to claim 1, wherein:
a first data item written with the first write mode, prior to a soldering of the device, has a stable value during the soldering; or
a second data item written with the second write mode, prior to the soldering of the device, has a value that is not stable during the soldering.

11. The device according to claim 1, wherein the first write mode comprises an application of a first current pulse having a different shape from a second current pulse of the second write mode.

12. The device according to claim 1,
wherein a first maximum number of write cycles of the second write mode is at least two times greater than a second maximum number of write cycles of the first write mode; or
wherein a crystallinity of memory sectors of the first memory after writing is different for the two write modes.

13. The device according to claim 1,
wherein the at least one finite state machine is arranged in a memory interface of the first memory; or
wherein the first memory comprises a plurality of memory banks, and the device comprises one state machine per memory bank.

14. The device according to claim 1, wherein the device is a microcontroller.

15. A method of operating an electronic device including a non-volatile phase-change memory having a first write mode and a second write mode, the first write mode having a different maximum number of write cycles than the second write mode, the method comprising:
copying, by a finite state machine, data from the first memory written with the first write mode; and
rewriting, by the finite state machine, the copied data with the second write mode.

16. The method according to claim 15, further comprising rewriting, by the finite state machine, the copied data with the second write mode in place of the data written with the first write mode.

17. The method according to claim 15, further comprising storing, by the finite state machine, the copied data in a volatile memory.

18. The method according to claim 15, wherein the data are in a form of a word and a header containing information indicating the first or second write mode used to write the word.

19. The method according to claim 15, wherein:
a first data item written with the first write mode prior to a soldering of the device, has a stable value during the soldering; or
a second data item written with the second write mode prior to the soldering of the device, has a value that is not stable during the soldering.

20. The method according to claim 15, wherein the first write mode comprises an application of a first current pulse having a different shape from a second current pulse of the second write mode.
